(19) United States
(12) Patent Application Publication
(10) Pub. No.: US 2024/0427715 A1
(43) Pub. Date: Dec. 26, 2024

(54) OPTICAL MEMORY MODULE AND OPTICAL COMPUTING SYSTEM INCLUDING THE SAME

(71) Applicant: SAMSUNG ELECTRONICS CO., LTD., Suwon-si (KR)

(72) Inventors: JOONHO JUN, Suwon-si (KR); Minwoo LEE, Suwon-si (KR); Byoungkon JO, Suwon-si (KR); Duksung KIM, Suwon-si (KR); Doohee HWANG, Suwon-si (KR)

(21) Appl. No.: 18/588,099

(22) Filed: Feb. 27, 2024

(30) Foreign Application Priority Data
Jun. 22, 2023 (KR) 10-2023-0080276

(51) Int. Cl. G06F 13/16; G06F 13/40; G11C 11/42

(52) U.S. Cl. CPC G06F 13/1694; G06F 13/4068; G11C 11/42

(57) ABSTRACT

An optical memory module includes a substrate, a first memory controller on the substrate, and a plurality of first memory devices on the substrate. The first memory controller includes the first transceiver. The first transceiver receives a first optical input signal through a first optical interconnection or outputs a first optical output signal through the first optical interconnection. The first memory controller is optically connected to an optical logic module located outside the optical memory module through the first transceiver and the first optical interconnection. The plurality of first memory devices are controlled by the first memory controller and accessed by the optical logic module through the first memory controller, the first transceiver and the first optical interconnection.

### CROSS-REFERENCE TO RELATED APPLICATION

This application claims priority under 35 USC § 119 to Korean Patent Application No. 10-2023-0080276, filed on Jun. 22, 2023, in the Korean Intellectual Property Office (KIPO), the contents of which are herein incorporated by reference in their entirety.

### BACKGROUND

### 1. Field

Example embodiments relate generally to semiconductor integrated circuits, and more particularly, to optical memory modules and optical computing systems including the optical memory modules.

### 2. Description of the Related Art

Recently, it has become desirable to increase a memory bandwidth for high performance computing, e.g., an artificial intelligence (AI) and a graphic processing unit (GPU). As an AI is applied in various fields, large amounts of memory resources are required for AI calculation and/or learning. For example, a GPU used for the AI calculation may access huge amounts of memory at high speed, and AI workloads may continue to require high memory bandwidth to implement high-density computation structures in the GPU. If the memory capacity is not sufficient, performance may be degraded when executing a process. Therefore, various methods to increase the memory capacity are being proposed.

### SUMMARY

According to example embodiments, an optical memory module may include a substrate, a first memory controller on the substrate, and a plurality of first memory devices on the substrate. The first memory controller includes the first transceiver. The first transceiver receives a first optical input signal through a first optical interconnection or outputs a first optical output signal through the first optical interconnection. The first memory controller is optically connected to an optical logic module located outside the optical memory module through the first transceiver and the first optical interconnection. The plurality of first memory devices are controlled by the first memory controller and accessed by the optical logic module through the first memory controller, the first transceiver and the first optical interconnection.

According to example embodiments, an optical computing system may include an optical logic module, a first optical memory module and a first optical interconnection. The first optical memory module optically communicates with the optical logic module. The first optical interconnection optically connects the optical logic module with the first optical memory module. The optical logic module includes a first substrate, and a first processing device on the first substrate. The first processing device includes a first transceiver. The first transceiver outputs a first optical signal through the first optical interconnection or receives a second optical signal through the first optical interconnection. The first processing device is optically connected to the first optical memory module through the first transceiver and the first optical interconnection. The first optical memory module includes a second substrate, a first memory controller on the second substrate, and a plurality of first memory devices on the second substrate. The first memory controller includes a second transceiver. The second transceiver receives the first optical signal through the first optical interconnection or outputs the second optical signal through the first optical interconnection. The first memory controller is optically connected to the optical logic module through the second transceiver and the first optical interconnection. The plurality of first memory devices are controlled by the first memory controller and accessed by the optical logic module through the first memory controller, the second transceiver and the first optical interconnection.

According to example embodiments, an optical memory module may include a substrate, a first memory controller on the substrate, a plurality of first memory devices on the substrate, a second memory controller on the substrate, and a plurality of second memory devices on the substrate. The first memory controller includes a first transceiver. The first transceiver receives a first optical input signal through a first optical interconnection or outputs a first optical output signal through the first optical interconnection. The first memory controller is optically connected to an optical logic module located outside the optical memory module through the first transceiver and the first optical interconnection. The plurality of first memory devices are controlled by the first memory controller and accessed by the optical logic module through the first memory controller, the first transceiver and the first optical interconnection. The second memory controller includes a second transceiver. The second transceiver receives a second optical input signal through a second optical interconnection or outputs a second optical output signal through the second optical interconnection. The second memory controller is optically connected to the optical logic module through the second transceiver and the second optical interconnection. The plurality of second memory devices are controlled by the second memory controller and accessed by the optical logic module through the second memory controller, the second transceiver and the second optical interconnection. The first transceiver includes a photonic integrated circuit (PIC), an electrical integrated circuit (EIC) and a serializer and deserializer (SERDES). The photonic integrated circuit generates a first electrical input signal based on the first optical input signal or generates the first optical output signal based on a first electrical output signal. The electrical integrated circuit generates a first signal based on the first electrical input signal or generates the first electrical output signal based on a second signal. The first signal is provided to the first memory controller and the plurality of first memory devices. The second signal is provided from the first memory controller and the plurality of first memory devices. The serializer and deserializer performs a serial-to-parallel conversion on the first signal or performs a parallel-to-serial conversion on the second signal. The optical memory module is a disaggregated package that is physically separated from the optical logic module, and is connected to the optical logic module through the first and second optical interconnections without an interposer.

### BRIEF DESCRIPTION OF THE DRAWINGS

Features will become apparent to those of skill in the art by describing in detail exemplary embodiments with reference to the attached drawings, in which:

FIG. 1 is a block diagram illustrating an optical memory module and an optical computing system including the optical memory module according to example embodiments.

FIG. 2 is a cross-sectional view of an example of an optical memory module according to example embodiments.

FIG. 3 is a cross-sectional view of an example of an optical logic module according to example embodiments.

FIGS. 4A and 4B are block diagrams illustrating examples of a transceiver included in an optical memory module according to example embodiments.

FIGS. 5A and 5B are block diagrams illustrating examples of a transceiver included in an optical logic module according to example embodiments.

FIGS. 6A and 6B are cross-sectional views of examples of an optical memory module according to example embodiments.

FIG. 7 is a block diagram illustrating an example of a memory device included in an optical memory module according to example embodiments.

FIG. 8 is a block diagram illustrating an example of a memory controller included in an optical memory module according to example embodiments.

FIGS. 9 and 10 are block diagrams illustrating an optical memory module and an optical computing system including the optical memory module according to example embodiments.

FIGS. 11A and 11B are cross-sectional views of examples of an optical logic module according to example embodiments.

FIG. 12 is a block diagram illustrating an optical memory module and an optical computing system including the optical memory module according to example embodiments.

FIG. 13 is a block diagram illustrating an electronic system according to example embodiments.

FIG. 14 is a block diagram illustrating a data center including a storage device according to example embodiments.

### DETAILED DESCRIPTION

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

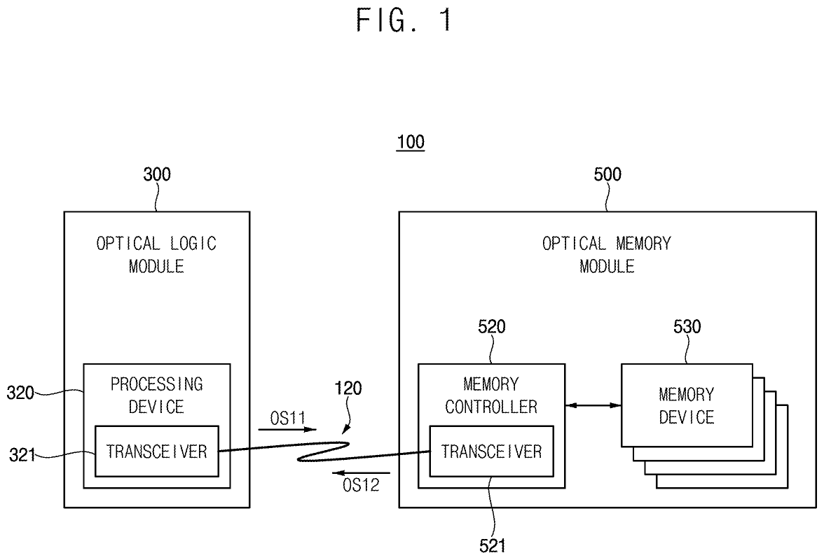

FIG. 1 is a block diagram illustrating an optical memory module and an optical computing system including the optical memory module according to example embodiments.

Referring to FIG. 1, an optical computing system 100 may include an optical interconnection 120, an optical logic module 300, and an optical memory module 500.

The optical interconnection 120 optically connects the optical logic module 300 with the optical memory module 500. For example, the optical interconnection 120 may include a component, e.g., an optical fiber, that transmits an optical signal. The optical interconnection 120 may be referred to as an optical link.

In integrated circuits, optical interconnections (or interconnects) refer to any system of transmitting signals from one part of an integrated circuit to another using light. Optical interconnections have been the topic of study due to the high latency and power consumption incurred by conventional metal interconnections in transmitting electrical signals over long distances. In electrical interconnections, nonlinear signals (e.g., digital signals) are transmitted by copper wires conventionally, and these electrical wires all have resistance and capacitance which severely limits the rise time of signals when the dimension of the wires are scaled down. Optical solutions may be used to transmit signals through long distances to substitute interconnection between dies within the integrated circuit (IC) package. For example, to control optical signals inside the small IC package properly, microelectromechanical system (MEMS) technology may be used to integrate the optical components (e.g., optical waveguides, optical fibers, lens, mirrors, optical actuators, optical sensors, etc.) and the electronic components together efficiently.

The optical logic module 300 may be optically connected to the optical memory module 500 through the optical interconnection 120, and controls overall operations of the optical computing system 100. The optical memory module 500 may be optically connected to the optical logic module 300 through the optical interconnection 120, and stores data used in the operations of the optical computing system 100.

The optical logic module 300 and the optical memory module 500 may exchange optical signals OS11 and OS12. For example, the optical logic module 300 may output the first optical signal OS11 through the optical interconnection 120, and the optical memory module 500 may receive the first optical signal OS11 transmitted through the optical interconnection 120. For example, the optical memory module 500 may output the second optical signal OS12 through the optical interconnection 120, and the optical logic module 300 may receive the second optical signal OS12 transmitted through the optical interconnection 120.

Each of the optical signals OS11 and OS12 may be defined as an optical input signal or an optical output signal with respect to one of the optical logic module 300 and the optical memory module 500. For example, from the perspective of the optical logic module 300, the first optical signal OS11 may be defined as an optical output signal, and the second optical signal OS12 may be defined as an optical input signal. For example, from the perspective of the optical memory module 500, the first optical signal OS11 may be defined as an optical input signal, and the second optical signal OS12 may be defined as an optical output signal.

In some example embodiments, the optical signals OS11 and OS12 may be signals associated with or related to data write/read operations performed on the optical memory module 500. For example, when a data write operation is to be performed on the optical memory module 500, the optical logic module 300 may transmit the first optical signal OS11, which includes a write request (or command), a write address and write data, to the optical memory module 500. For example, when a data read operation is to be performed on the optical memory module 500, the optical logic module 300 may transmit the first optical signal OS11, which includes a read request (or command) and a read address, to the optical memory module 500, and the optical memory module 500 may transmit the second optical signal OS12, which includes read data, to the optical logic module 300. In another example, the optical signals OS11 and OS12 may be signals associated with at least one of various operations of the optical computing system 100, the optical logic module 300, and/or the optical memory module 500.

The optical logic module 300 may include a processing device 320. The processing device 320 controls an operation of the optical logic module 300, and performs various functions, computations, jobs and/or tasks. For example, the processing device 320 may be one of a central processing unit (CPU), a graphic processing unit (GPU), a neural processing unit (NPU) and a system-on-chip (SoC). The processing device 320 may operate as a host for the optical memory module 500, and may be referred to as a logic semiconductor device.

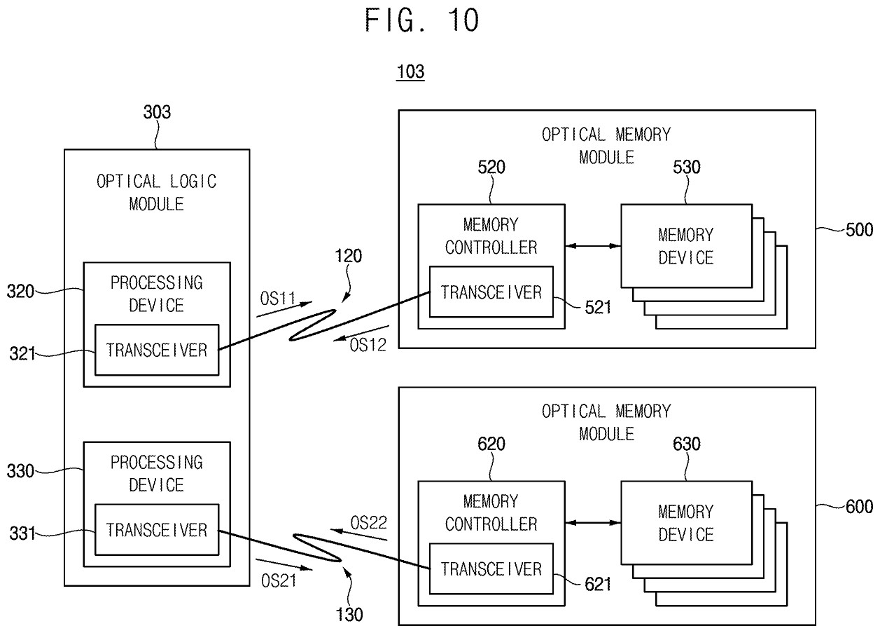

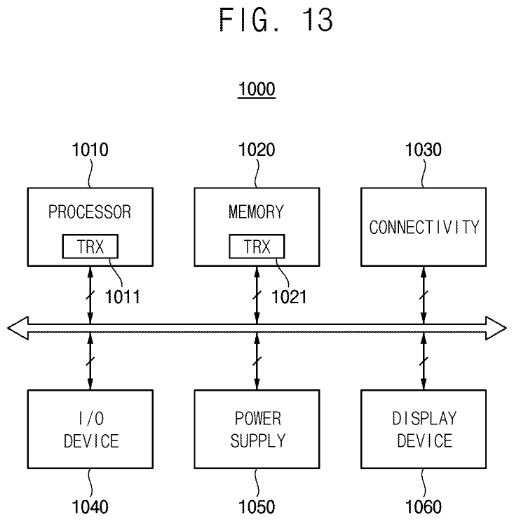

For example, as illustrated in FIG. 1, the optical logic module 300 may include a single processing device 320. In another example, as will be described with reference to FIGS. 10 and 12, the optical logic module may include two or more processing devices.

The processing device 320 may include a transceiver 321. The transceiver 321 is located or disposed in the processing device 320, and is directly connected to the optical interconnection 120. The transceiver 321 outputs the first optical signal OS11 through the optical interconnection 120 or receives the second optical signal OS12 through the optical interconnection 120. The processing device 320 is optically connected to the optical memory module 500 through the transceiver 321 and the optical interconnection 120. The transceiver 321 may be referred to as an optical transceiver.

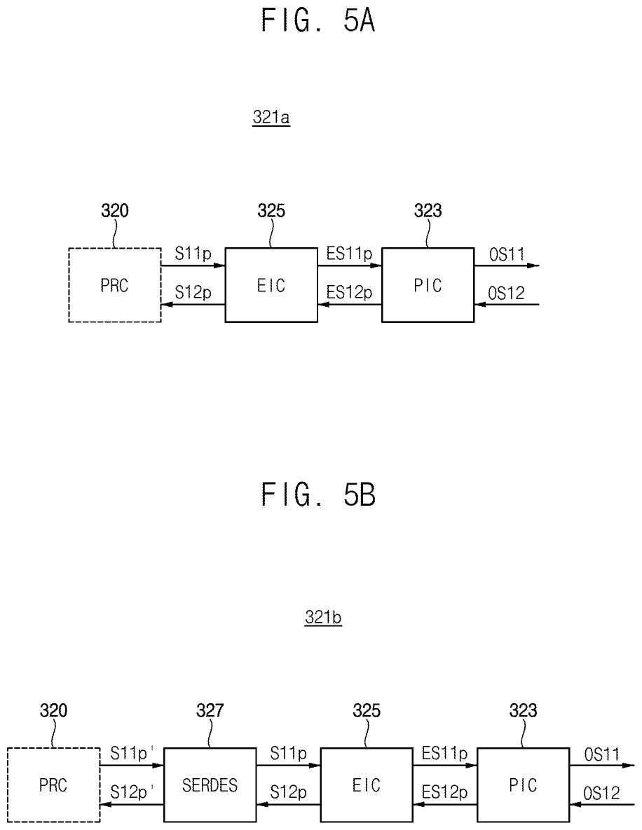

An example of the optical logic module 300 will be described with reference to FIG. 3, and examples of the transceiver 321 will be described with reference to FIGS. 5A and 5B.

The optical memory module 500 may include a memory controller 520 and a plurality of memory devices 530. The memory controller 520 controls an operation of the optical memory module 500. The plurality of memory devices 530 are controlled by the memory controller 520 and store data. For example, each of the plurality of memory devices 530 may be a memory device disposed adjacent to a logic semiconductor device. For example, each of the plurality of memory devices 530 may be one of a high bandwidth memory (HBM) device and a graphic double data rate (GDDR) memory device.

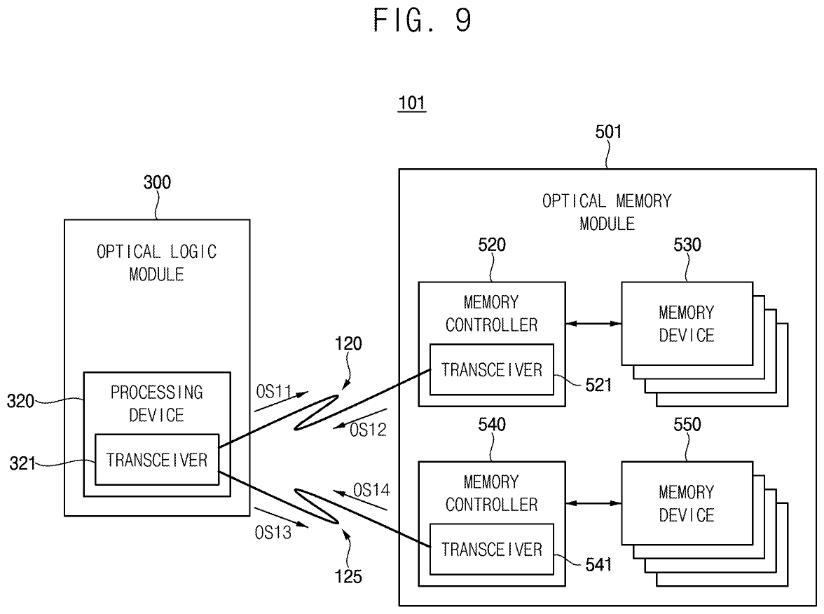

For example, as illustrated in FIG. 1, the optical memory module 500 may include a single memory controller 520 and the memory devices 530 connected thereto. In another example, as will be described with reference to FIG. 9, the optical memory module may include two or more memory controllers and memory devices connected thereto.

The memory controller 520 may include a transceiver 521. The transceiver 521 is located or disposed in the memory controller 520, and is directly connected to the optical interconnection 120. The transceiver 521 receives the first optical signal OS11 through the optical interconnection 120 or outputs the second optical signal OS12 through the optical interconnection 120. The memory controller 520 is optically connected to the optical logic module 300 through the transceiver 521 and the optical interconnection 120.

The plurality of memory devices 530 are accessed by the optical logic module 300 through the memory controller 520, the transceiver 521, and the optical interconnection 120. For example, under the control of the optical logic module 300, the data write/read operations may be performed on the optical memory module 500 (e.g., on the plurality of memory devices 530).

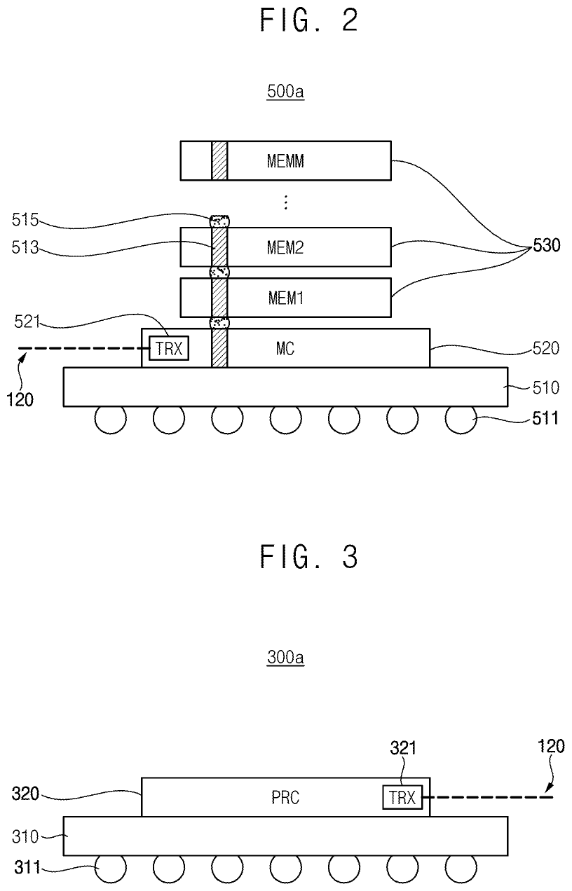

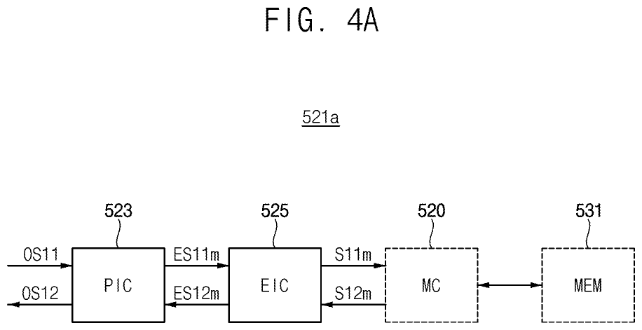

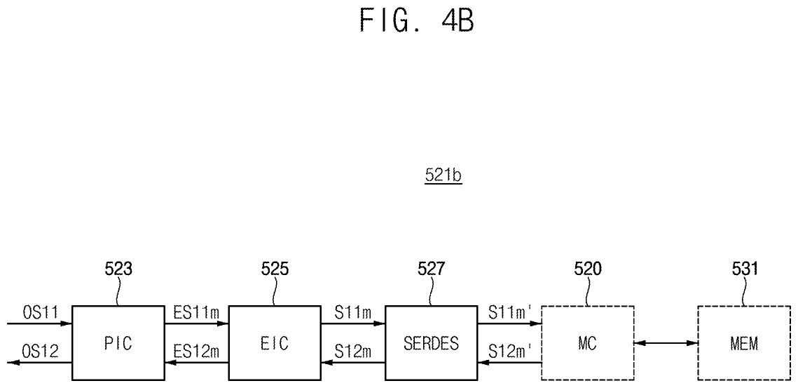

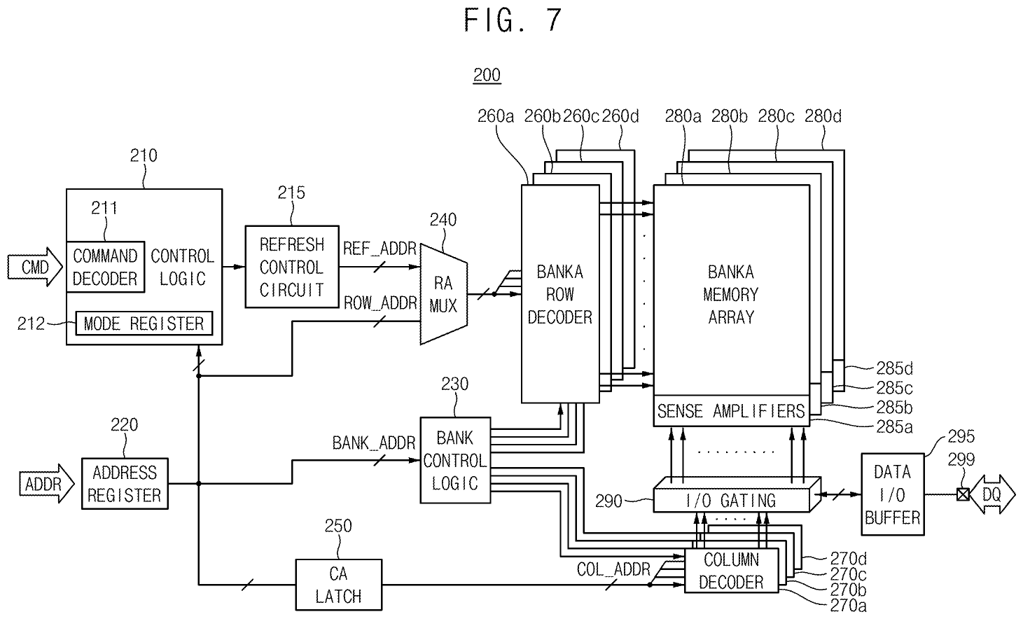

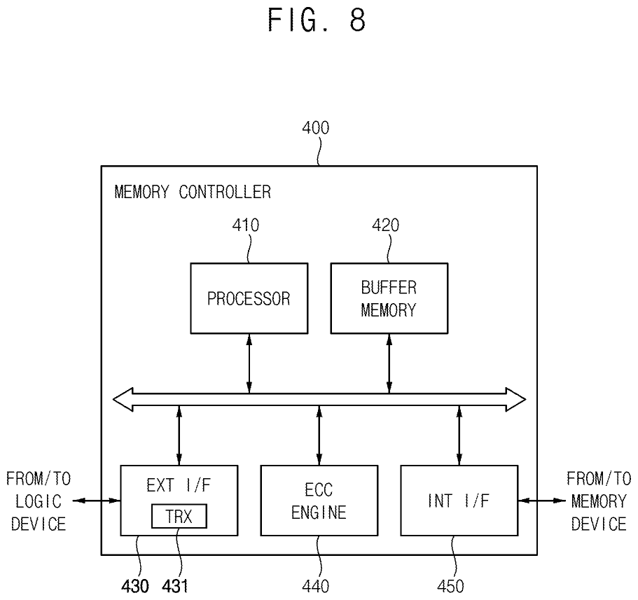

An example of the optical memory module 500 will be described with reference to FIG. 2, and examples of the transceiver 521 will be described with reference to FIGS. 4A and 4B. In addition, an example of the memory devices 530 and an example of the memory controller 520 will be described with reference to FIGS. 7 and 8, respectively.

In some example embodiments, the optical logic module 300 and the optical memory module 500 may be disaggregated packages that are physically separated from each other. In other words, the optical logic module 300 and the optical memory module 500 may not be included in a single package, and may be manufactured independently (e.g., individually) and then optically connected through the optical interconnection 120.

In the optical memory module 500 and the optical computing system 100 according to example embodiments, the memory disaggregation may be implemented using co-packaged optics (CPO) technology. For example, the optical logic module 300 including the processing device 320 and the optical memory module 500 including memory devices 530 may be implemented in the disaggregated or separate packages, rather than implementing the processing device 320 and the memory devices 530 in a single package, and the optical logic module 300 and the optical memory module 500 may be optically connected through the optical interconnection 120. In addition, the transceivers 321 and 521 for connection to the optical interconnection 120 may be formed within the processing device 320 and the memory controller 520, respectively. Accordingly, capacity (or density) and bandwidth of the memory devices connected to one processing device may be efficiently expanded, manufacturing cost may be reduced by connecting the processing device with the memory devices without the interposer, and problems, e.g., heat generation, power consumption and size constraints, may be efficiently resolved.

FIG. 2 is a cross-sectional view of an example of an optical memory module according to example embodiments.

Referring to FIG. 2, an optical memory module 500a may include a substrate 510, a memory controller (MC) 520 and a plurality of memory devices (MEM1, MEM2, . . . , MEMM) 530. A memory module may be referred to as a memory package, a memory chip, or the like.

The substrate 510 may have an upper surface and a lower surface that are opposite to each other. For example, the substrate 510 may be a printed circuit board (PCB). The PCB may be a multilayered circuit board including vias and various circuits therein. The substrate 510 may be referred to as a base substrate, a package substrate, or the like.

The memory controller 520 and the plurality of memory devices 530 may be formed or disposed on the substrate 510. In an example of FIG. 2, the memory controller 520 and the plurality of memory devices 530 may be sequentially stacked on the substrate 510 in a vertical direction. For example, the memory controller 520 may be formed on the substrate 510, and the plurality of memory devices 530 may be sequentially stacked or arranged on the memory controller 520.

As described with reference to FIG. 1, the memory controller 520 may include a transceiver (TRX) 521. The transceiver 521 may be directly connected to the optical interconnection 120. The memory controller 520 may be optically connected to the optical logic module 300 through the transceiver 521 and the optical interconnection 120.

The plurality of memory devices 530 may include first to M-th memory devices that are sequentially stacked in the vertical direction, where M is a positive integer greater than or equal to two.

Each of the memory controller 520 and the plurality of memory devices 530 may include through silicon vias (TSVs) 513. For example, each through silicon via 513 may be formed by penetrating a portion of or a whole of a semiconductor substrate included in one of the memory controller 520 and the plurality of memory devices 530. For example, the through silicon vias 513 may include data input/output (I/O) through silicon vias, command through silicon vias, address through silicon vias, etc.

In some example embodiment, with respect to each of the memory controller 520 and the plurality of memory devices 530, the through silicon vias 513 may be arranged at the same locations in each of the memory controller 520 and the plurality of memory devices 530. As such, the memory controller 520 and the plurality of memory devices 530 may be stacked such that the through silicon vias 513 of each of the memory controller 520 and the plurality of memory devices 530 may be completely overlapped (e.g., aligned) in the vertical direction (e.g., arrangements of the through silicon vias 513 may be perfectly matched in the memory controller 520 and the plurality of memory devices 530). In such a stacked state, the memory controller 520 and the plurality of memory devices 530 may be electrically connected to one another and the substrate 510 through the through silicon vias 513 and conductive material 515.

External connectors 511 for an electrical connection with an external device may be disposed on the lower surface of the substrate 510. For example, the external connectors 511 may be solder balls (e.g., ball grid arrays (BGAs)). The optical memory module 500a may be mounted on a module substrate by the external connectors 511.

For example, a sealing member may be formed on the substrate 510, the memory controller 520, and the plurality of memory devices 530, such that the memory controller 520 and the plurality of memory devices 530 are fixed by the sealing member. For example, a heat sink may be disposed on the substrate 510, the memory controller 520, and the plurality of memory devices 530, such that heat generated from the memory controller 520 and the plurality of memory devices 530 is dissipated by the heat sink.

FIG. 3 is a cross-sectional view of an example of an optical logic module according to example embodiments. Descriptions that are repetitive relative to FIG. 2 will be omitted.

Referring to FIG. 3, an optical logic module 300a may include a substrate 310 and a processing device (PRC) 320. A logic module may be referred to as a logic package, a logic chip, or the like.

The substrate 310 may be substantially the same as the substrate 510 in FIG. 2. The substrates 310 and 510 may be physically separate substrates.

The processing device 320 may be formed or disposed on the substrate 310. As described with reference to FIG. 1, the processing device 320 may include a transceiver (TRX) 321. The transceiver 321 may be directly connected to the optical interconnection 120. The processing device 320 may be optically connected to the optical memory module 500 through the transceiver 321 and the optical interconnection 120. External connectors 311 for an electrical connection with an external device may be disposed on a lower surface of the substrate 310.

As described with reference to FIGS. 2 and 3, the processing device 320 and the plurality of memory devices 530 may be formed on the substrates 310 and 510, which are physically separated from each other, respectively, and thus the optical logic module 300a and the optical memory module 500a may be implemented as disaggregated or separate packages. In addition, the processing device 320 and the plurality of memory devices 530 may be connected without an interposer using the optical interconnection 120 and the transceivers 321 and 521.

FIGS. 4A and 4B are block diagrams illustrating examples of a transceiver included in an optical memory module according to example embodiments.

Referring to FIG. 4A, a transceiver 521a may include a photonic integrated circuit (PIC) 523 and an electrical integrated circuit (EIC) 525.

The photonic integrated circuit 523 may generate a first electrical signal ES11m based on the first optical signal OS11 received through the optical interconnection 120, or may generate the second optical signal OS12 output through the optical interconnection 120 based on a second electrical signal ES12m. In other words, the photonic integrated circuit 523 may perform an optical-to-electrical (O/E) conversion and/or an electrical-to-optical (E/O) conversion. For example, the photonic integrated circuit 523 may include a light source, e.g., a light emitting diode (LED), a laser, or the like.

The electrical integrated circuit 525 may generate a first signal S11m provided to the memory controller 520 and a memory device (MEM) 531 based on the first electrical signal ES11m, or may generate the second electrical signal ES12m based on a second signal S12m provided from the memory controller 520 and the memory device 531. The memory device 531 may be one of the plurality of memory devices 530.

A photonic integrated circuit or integrated optical circuit is a microchip containing two or more photonic components which form a functioning circuit. This technology detects, generates, transports, and processes light. Photonic integrated circuits utilize photons (or particles of light) as opposed to electrons that are utilized by electronic integrated circuits. The major difference between the two is that a photonic integrated circuit provides functions for information signals imposed on optical wavelengths typically in the visible spectrum or near infrared (about 850 to 1650 nm). For example, the most commercially utilized material platform for photonic integrated circuits is indium phosphide (InP), which allows for the integration of various optically active and passive functions on the same chip. For example, all modern monolithic tunable lasers, widely tunable lasers, externally modulated lasers and transmitters, integrated receivers, etc. are examples of photonic integrated circuits.

In some example embodiments, the signals S11m and S12m exchanged between the electrical integrated circuit 525 and the memory controller 520 may be signals based on a universal chiplet interconnect express (UCIe) protocol. The UCIe is an open specification for a die-to-die interconnect and serial bus between chiplets. However, signals based on other various protocols may be used.

Referring to FIG. 4B, a transceiver 521b may include a photonic integrated circuit 523, an electrical integrated circuit 525, and a serializer and deserializer (SERDES) 527. Descriptions that are repetitive relative to FIG. 4A will be omitted.

The transceiver 521b may be substantially the same as the transceiver 521a of FIG. 4A, except that the transceiver 521b further includes the serializer and deserializer 527.

The serializer and deserializer 527 may perform a serial-to-parallel conversion and/or a parallel-to-serial conversion. For example, the serializer and deserializer 527 may perform a serial-to-parallel conversion on the first signal S11m to generate a signal S11m′ provided to the memory controller 520 and the memory device 531. For example, the serializer and deserializer 527 may perform a parallel-to-serial conversion on a signal S12m′ provided from the memory controller 520 and the memory device 531 to generate the second signal S12m. In other words, the signals S11m′ and S12m′ between the serializer and deserializer 527 and the memory controller 520 may be parallel signals, and the signals S11m and S12m between the electrical integrated circuit 525 and the serializer and deserializer 527 may be serial signals.

FIGS. 5A and 5B are block diagrams illustrating examples of a transceiver included in an optical logic module according to example embodiments. Descriptions that are repetitive relative to FIGS. 4A and 4B will be omitted.

Referring to FIG. 5A, a transceiver 321a may include a photonic integrated circuit 323 and an electrical integrated circuit 325.

The photonic integrated circuit 323 may be substantially the same as the photonic integrated circuit 523 in FIG. 4A. The photonic integrated circuit 323 may generate the first optical signal OS11 output through the optical interconnection 120 based on a first electrical signal ES11p, or may generate a second electrical signal ES12p based on the second optical signal OS12 received through the optical interconnection 120.

The electrical integrated circuit 325 may be substantially the same as the electrical integrated circuit 525 in FIG. 4A. The electrical integrated circuit 325 may generate the first electrical signal ES11p based on a first signal S11p provided from the processing device 320, or may generate a second signal S12p provided to the processing device 320 based on the second electrical signal ES12p.

Referring to FIG. 5B, a transceiver 321b may include a photonic integrated circuit 323, an electrical integrated circuit 325, and a serializer and deserializer 327.

The transceiver 321b may be substantially the same as the transceiver 321a of FIG. 5A, except that the transceiver 321b further includes the serializer and deserializer 327.

The serializer and deserializer 327 may be substantially the same as the serializer and deserializer 527 in FIG. 4B. The serializer and deserializer 327 may perform a serial-to-parallel conversion and/or a parallel-to-serial conversion. For example, the serializer and deserializer 327 may perform a parallel-to-serial conversion on a signal S11p′ provided from the processing device 320 to generate the first signal S11p. For example, the serializer and deserializer 327 may perform a serial-to-parallel conversion on the second signal S12p to generate a signal S12p′ provided to the processing device 320.

In some example embodiments, during the data write operation, the first optical signal OS11 may include the write request, the write address and the write data, as described with reference to FIG. 1. Similarly, during the data write operation, each of the signals S11p′, S11p and ES11p for generating the first optical signal OS11 in the processing device 320 and the transceivers 321a and 321b may include the write request, the write address and the write data. In addition, during the data write operation, each of the signals ES11m, S11m and S11m′ generated based on the first optical signal OS11 in the memory controller 520 and the transceivers 521a and 521b may include the write request, the write address and the write data.

In some example embodiments, during the data read operation, the first optical signal OS11 may include the read request and the read address, and the second optical signal OS12 may include the read data, as described with reference to FIG. 1. Similarly, during the data read operation, each of the signals S11p′, S11p and ES11p for generating the first optical signal OS11 in the processing device 320 and the transceivers 321a and 321b may include the read request and the read address, and each of the signals ES11m, S11m and S11m′ generated based on the first optical signal OS11 in the memory controller 520 and the transceivers 521a and 521b may include the read request and the read address. In addition, during the data read operation, each of the signals S12m′, S12m and ES12m for generating the second optical signal OS12 in the memory controller 520 and the transceivers 521a and 521b may include the read data, and each of the signals ES12p, S12p and S12p′ generated based on the second optical signal OS12 in the processing device 320 and the transceivers 321a and 321b may include the read data.

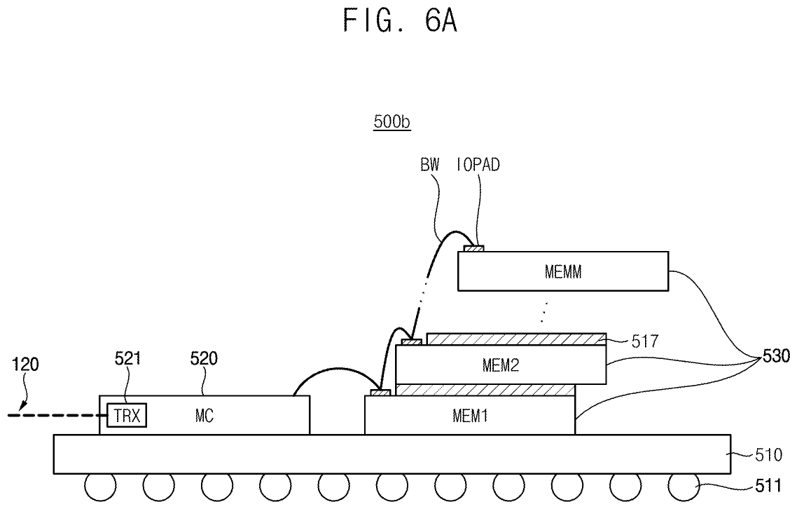

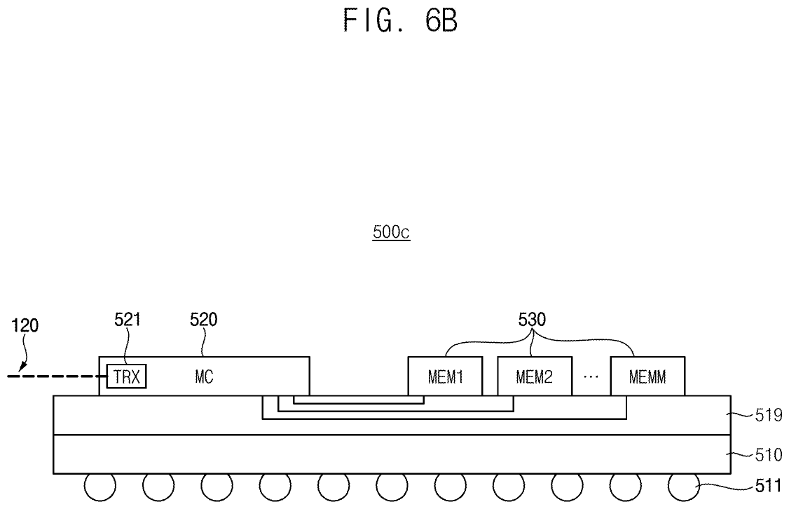

FIGS. 6A and 6B are cross-sectional views of examples of an optical memory module according to example embodiments. Descriptions that are repetitive relative to FIG. 2 will be omitted.

Referring to FIG. 6A, an optical memory module 500b may include a substrate 510, a memory controller 520, and a plurality of memory devices 530.

In an example of FIG. 6A, the memory controller 520 and the plurality of memory devices 530 may be spaced apart from each other on the substrate 510, and the plurality of memory devices 530 may be sequentially stacked on the substrate 510 in the vertical direction.

Each of the plurality of memory devices 530 may include input/output (I/O) pads (IOPAD). For example, the input/output pads IOPAD may include data input/output pads, command pads, address pads, etc.

In some example embodiments, the plurality of memory devices 530 may be stacked on the substrate 510 such that a surface on which the input/output pads IOPAD may be disposed faces upwards. In some example embodiments, with respect to each of the plurality of memory devices 530, the input/output pads IOPAD may be arranged near one side of each of the plurality of memory devices 530. As such, the plurality of memory devices 530 may be stacked scalariformly, i.e., in a step shape, such that the input/output pads IOPAD of each of the plurality of memory devices 530 may be exposed (e.g., the input/output pads IOPAD may be exposed on the edge of each step). In such stacked state, the plurality of memory devices 530 may be electrically connected to each other and the memory controller 520 through the input/output pads IOPAD and bonding wires BW. In some example embodiments, adhesive members 517 may intervene between the plurality of memory devices 530.

Referring to FIG. 6B, an optical memory module 500c may include a substrate 510, a memory controller 520 and a plurality of memory devices 530.

In an example of FIG. 6B, the memory controller 520 and the plurality of memory devices 530 may be spaced apart from each other on the substrate 510, and the plurality of memory devices 530 may also be spaced apart from each other on the substrate 510.

An internal connection structure 519 may be formed between the substrate 510 and the memory controller 520 and the plurality of memory devices 530. The memory controller 520 and the plurality of memory devices 530 may be electrically connected through connection wires included in the internal connection structure 519.

In some example embodiments, the internal connection structure 519 may be a redistribution layer. For example, the redistribution layer may include a plurality of vias and a plurality of connection wires, and may include a plurality of insulating layers that electrically insulate at least some of the plurality of connection wires.

In some example embodiments, the internal connection structure 519 may be an interposer. For example, the interposer may include a plurality of through electrodes and a plurality of connection wires. For example, the interposer may be a silicon interposer including a silicon substrate, which is a semiconductor substrate, and the plurality of through electrodes may be through silicon vias penetrating the silicon substrate.

Although configurations of the optical memory module are described with reference to FIGS. 2, 6A and 6B, the optical memory module may be implemented by combining some of the configurations illustrated in FIGS. 2, 6A and 6B. For example, the memory devices 530 may be stacked on the memory controller 520 as illustrated in FIG. 2, and the memory controller 520 and the memory devices 530 may be electrically connected by the bonding wires BW in FIG. 6A. For example, the memory controller 520 and the memory devices 530 may be spaced apart from each other on the substrate 510 as illustrated in FIG. 6A, and the memory devices 530 may be electrically connected to each other by the through silicon vias 513 in FIG. 2, and the memory controller 520 and the memory devices 530 may be electrically connected by the bonding wires BW in FIG. 6A. For example, the memory controller 520 and the memory devices 530 may be connected by the internal connection structure 519 as illustrated in FIG. 6B, and the memory devices 530 may be sequentially stacked as illustrated in FIG. 2 or FIG. 6A.

FIG. 7 is a block diagram illustrating an example of a memory device included in an optical memory module according to example embodiments.

Referring to FIG. 7, a memory device 200 includes a control logic 210, a refresh control circuit 215, an address register 220, a bank control logic 230, a row address multiplexer 240, a column address latch 250, a row decoder, a column decoder, a memory cell array, a sense amplifier unit, an input/output (I/O) gating circuit 290, a data I/O buffer 295 and a data I/O pad 299. For example, the memory device 200 may be one of various volatile memory devices, e.g., a dynamic random access memory (DRAM).

The memory cell array may include a plurality of memory cells. The memory cell array may include a plurality of bank arrays, e.g., first to fourth bank arrays 280a, 280b, 280c and 280d. The row decoder may include a plurality of bank row decoders, e.g., first to fourth bank row decoders 260a, 260b, 260c and 260d connected to the first to fourth bank arrays 280a, 280b, 280c and 280d, respectively. The column decoder may include a plurality of bank column decoders, e.g., first to fourth bank column decoders 270a, 270b, 270c and 270d connected to the first to fourth bank arrays 280a, 280b, 280c and 280d, respectively. The sense amplifier unit may include a plurality of bank sense amplifiers, e.g., first to fourth bank sense amplifiers 285a, 285b, 285c and 285d connected to the first to fourth bank arrays 280a, 280b, 280c and 280d, respectively.

The first to fourth bank arrays 280a to 280d, the first to fourth bank row decoders 260a to 260d, the first to fourth bank column decoders 270a to 270d, and the first to fourth bank sense amplifiers 285a to 285d may form first to fourth banks, respectively. For example, the first bank array 280a, the first bank row decoder 260a, the first bank column decoder 270a, and the first bank sense amplifier 285a may form the first bank; the second bank array 280b, the second bank row decoder 260b, the second bank column decoder 270b, and the second bank sense amplifier 285b may form the second bank; the third bank array 280c, the third bank row decoder 260c, the third bank column decoder 270c, and the third bank sense amplifier 285c may form the third bank; and the fourth bank array 280d, the fourth bank row decoder 260d, the fourth bank column decoder 270d, and the fourth bank sense amplifier 285d may form the fourth bank.

The address register 220 may receive an address ADDR including a bank address BANK_ADDR, a row address ROW_ADDR and a column address COL_ADDR from a memory controller (e.g., from the memory controller 520 in FIG. 1) located outside the memory device 200. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to receipt of the bank address BANK_ADDR. One of the first to fourth bank row decoders 260a to 260d corresponding to the received bank address BANK_ADDR may be activated in response to the bank control signals generated by the bank control logic 230, and one of the first to fourth bank column decoders 270a to 270d corresponding to the received bank address BANK_ADDR may be activated in response to the bank control signals generated by the bank control logic 230.

The refresh control circuit 215 may generate a refresh address REF_ADDR in response to receipt of a refresh command or entrance of any self-refresh mode. For example, the refresh control circuit 215 may include a refresh counter that is configured to sequentially change the refresh address REF_ADDR from a first address of the memory cell array to a last address of the memory cell array. The refresh control circuit 215 may receive control signals from the control logic 210.

The row address multiplexer 240 may receive the row address ROW_ADDR from the address register 220, and may receive the refresh address REF_ADDR from the refresh control circuit 215. The row address multiplexer 240 may selectively output the row address ROW_ADDR or the refresh address REF_ADDR. A row address (e.g., the row address ROW_ADDR or the refresh address REF_ADDR) output from the row address multiplexer 240 may be applied to the first to fourth bank row decoders 260a to 260d.

The activated one of the first to fourth bank row decoders 260a to 260d may decode the row address output from the row address multiplexer 240, and may activate a wordline corresponding to the row address. For example, the activated bank row decoder may apply a wordline driving voltage to the wordline corresponding to the row address.

The column address latch 250 may receive the column address COL_ADDR from the address register 220, and may temporarily store the received column address COL_ADDR. The column address latch 250 may apply the temporarily stored or received column address COL_ADDR to the first to fourth bank column decoders 270a to 270d.

The activated one of the first to fourth bank column decoders 270a to 270d may decode the column address COL_ADDR output from the column address latch 250, and may control the I/O gating circuit 290 to output data corresponding to the column address COL_ADDR.

The I/O gating circuit 290 may include a circuitry for gating I/O data. For example, although not shown, the I/O gating circuit 290 may include an input data mask logic, read data latches for storing data output from the first to fourth bank arrays 280a to 280d, and write drivers for writing data to the first to fourth bank arrays 280a to 280d.

Data DQ to be read from one of the first to fourth bank arrays 280a to 280d may be sensed by a sense amplifier coupled to the one bank array, and may be stored in the read data latches. The data DQ stored in the read data latches may be provided to the memory controller via the data I/O buffer 295 and the data I/O pad 299. Data DQ received via the data I/O pad 299 that are to be written to one of the first to fourth bank arrays 280a to 280d may be provided from the memory controller to the data I/O buffer 295. The data DQ received via the data I/O pad 299 and provided to the data I/O buffer 295 may be written to the one bank array via the write drivers in the I/O gating circuit 290.

The control logic 210 may control an operation of the memory device 200. For example, the control logic 210 may generate control signals for the memory device 200 to perform a data write operation or a data read operation. The control logic 210 may include a command decoder 211 that decodes a command CMD received from the memory controller and a mode register 212 that sets an operation mode of the memory device 200. For example, the command decoder 211 may generate the control signals corresponding to the command CMD by decoding a write enable signal (e.g., /WE), a row address strobe signal (e.g., /RAS), a column address strobe signal (e.g., /CAS), a chip select signal (e.g., /CS), etc. The control logic 210 may further receive a clock signal (e.g., CLK) and a clock enable signal (e.g., /CKE) for operating the memory device 200 in a synchronous scheme.

Although the memory device included in the optical memory module according to example embodiments is described based on a DRAM, the memory device according to example embodiments may be any volatile memory device and/or any nonvolatile memory, device e.g., a static random access memory (SRAM), a flash memory, a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), a thyristor random access memory (TRAM), etc.

FIG. 8 is a block diagram illustrating an example of a memory controller included in an optical memory module according to example embodiments.

Referring to FIG. 8, a memory controller 400 may include at least one processor 410, a buffer memory 420, an external interface (EXT I/F) 430, an error correction code (ECC) engine 440 and an internal interface (INT I/F) 450.

The processor 410 may control an operation of the memory controller 400 in response to commands and/or requests received from an optical logic module (e.g., the optical logic module 300 and/or the processing device 320 in FIG. 1) located outside the memory controller 400. For example, the processor 410 may control an operation of an optical memory module (e.g., the optical memory module 500 in FIG. 1), and may control respective components by employing firmware for operating the optical memory module.

The buffer memory 420 may store instructions and data executed and processed by the processor 410. For example, the buffer memory 420 may be implemented with a volatile memory, e.g., a DRAM, a SRAM, a cache memory, etc.

The ECC engine 440 for error correction may perform coded modulation using a Bose-Chaudhuri-Hocquenghem (BCH) code, a low density parity check (LDPC) code, a turbo code, a Reed-Solomon code, a convolution code, a recursive systematic code (RSC), a trellis-coded modulation (TCM), a block coded modulation (BCM), etc., or may perform ECC encoding and ECC decoding using above-described codes or other error correction codes.

The external interface 430 may provide physical connections between the optical logic module and the memory controller 400. The external interface 430 may provide an interface corresponding to a bus format of the optical logic module for communication between the optical logic module and the memory controller 400. For example, the external interface 430 may include a transceiver 431 for connection to an optical interconnection (e.g., the optical interconnection 120 in FIG. 1).

The internal interface 450 may provide physical connections between the memory controller 400 and a plurality of memory devices (e.g., the plurality of memory devices 530 in FIG. 1). For example, the internal interface 450 may be configured to comply with a standard protocol, e.g., Toggle or open NAND flash interface (ONFI).

FIGS. 9 and 10 are block diagrams illustrating an optical memory module and an optical computing system including the optical memory module according to example embodiments. The descriptions repeated with FIG. 1 will be omitted.

Referring to FIG. 9, an optical computing system 101 includes optical interconnections 120 and 125, an optical logic module 300 and an optical memory module 501.

The optical computing system 101 may be substantially the same as the optical computing system 100 of FIG. 1, except that the optical computing system 101 further includes the optical interconnection 125 and a configuration of the optical memory module 501 is partially changed. The optical interconnection 120 and the optical logic module 300 may be substantially the same as those described with reference to FIG. 1.

As with the optical interconnection 120, the optical interconnection 125 may optically connect the optical logic module 300 with the optical memory module 501. The optical logic module 300 and the optical memory module 501 may exchange optical signals OS13 and OS14. For example, the optical logic module 300 may output the third optical signal OS13 through the optical interconnection 125, and may receive the fourth optical signal OS14 transmitted through the optical interconnection 125. For example, the optical memory module 501 may receive the third optical signal OS13 transmitted through the optical interconnection 125, and may output the fourth optical signal OS14 through the optical interconnection 125.

The optical memory module 501 may include memory controllers 520 and 540 and a plurality of memory devices 530 and 550. The memory controller 520 and the plurality of memory devices 530 may be substantially the same as those described with reference to FIG. 1. The memory controller 540 and the plurality of memory devices 550 may be similar to the memory controller 520 and the plurality of memory devices 530, respectively.

The memory controller 540 may include a transceiver 541. The transceiver 541 may be located in the memory controller 540, and may be directly connected to the optical interconnection 125. The transceiver 541 may receive the third optical signal OS13 through the optical interconnection 125, or may output the fourth optical signal OS14 through the optical interconnection 125. The memory controller 540 may be optically connected to the optical logic module 300 through the transceiver 541 and the optical interconnection 125.

The plurality of memory devices 550 may be controlled by the memory controller 540, and may be accessed by the optical logic module 300 through the memory controller 540, the transceiver 541 and the optical interconnection 125.

As with the memory controller 520 and the plurality of memory devices 530, the memory controller 540 and the plurality of memory devices 550 may be formed on a substrate. For example, the memory controller 540 and the plurality of memory devices 550 may be implemented as described with reference to FIGS. 2, 6A and 6B. For example, the optical memory module 501 may be implemented as a single package, and thus the memory controllers 520 and 540 and the plurality of memory devices 530 and 550 may be disposed on the same substrate.

For example, as illustrated in FIG. 9, the optical memory module 501 may include two memory controllers 520 and 540 and the memory devices 530 and 550 connected thereto. In another example, the optical memory module may include three or more memory controllers and memory devices connected thereto.

Referring to FIG. 10, an optical computing system 103 includes optical interconnections 120 and 130, an optical logic module 303 and optical memory modules 500 and 600.

The optical computing system 103 may be substantially the same as the optical computing system 100 of FIG. 1, except that the optical computing system 103 further includes the optical interconnection 130 and the optical memory module 600 and a configuration of the optical logic module 303 is partially changed. The optical interconnection 120 and the optical logic module 300 may be substantially the same as those described with reference to FIG. 1.

As with the optical interconnection 120, the optical interconnection 130 may optically connect the optical logic module 303 with the optical memory module 600. The optical logic module 303 and the optical memory module 600 may exchange optical signals OS21 and OS22. For example, the optical logic module 303 may output the third optical signal OS21 through the optical interconnection 130, and may receive the fourth optical signal OS22 transmitted through the optical interconnection 130. For example, the optical memory module 600 may receive the third optical signal OS21 transmitted through the optical interconnection 130, and may output the fourth optical signal OS22 through the optical interconnection 130.

The optical logic module 303 may include processing devices 320 and 330. The processing device 320 may be substantially the same as that described with reference to FIG. 1. The processing device 330 may be similar to the processing device 320.

The processing device 330 may include a transceiver 331. The transceiver 331 may be located in the processing device 330, and may be directly connected to the optical interconnection 130. The transceiver 331 may output the third optical signal OS21 through the optical interconnection 130, or may receive the fourth optical signal OS22 through the optical interconnection 130. The processing device 330 may be optically connected to the optical memory module 600 through the transceiver 331 and the optical interconnection 130.

The optical memory module 600 may include a memory controller 620 and a plurality of memory devices 630, and the memory controller 620 may include a transceiver 621. The optical memory module 600, the memory controller 620, the transceiver 621 and the plurality of memory devices 630 may be substantially the same as the optical memory module 500, the memory controller 520, the transceiver 521 and the plurality of memory devices 530, respectively.

The memory controller 620 and the plurality of memory devices 630 may be formed on a substrate. For example, the memory controller 620 and the plurality of memory devices 630 may be implemented as described with reference to FIGS. 2, 6A and 6B. For example, the optical memory modules 500 and 600 may be implemented as different and separate packages, and thus the memory controllers 520 and 620 and the plurality of memory devices 530 and 630 may be disposed on different substrates.

For example, as illustrated in FIG. 10, the optical logic module 303 may include two processing devices 320 and 330 and the optical computing system 103 includes two optical memory modules 500 and 600 connected thereto. In another example, the optical logic module may include three or more processing devices, and the optical computing system may include three or more optical memory modules connected thereto.

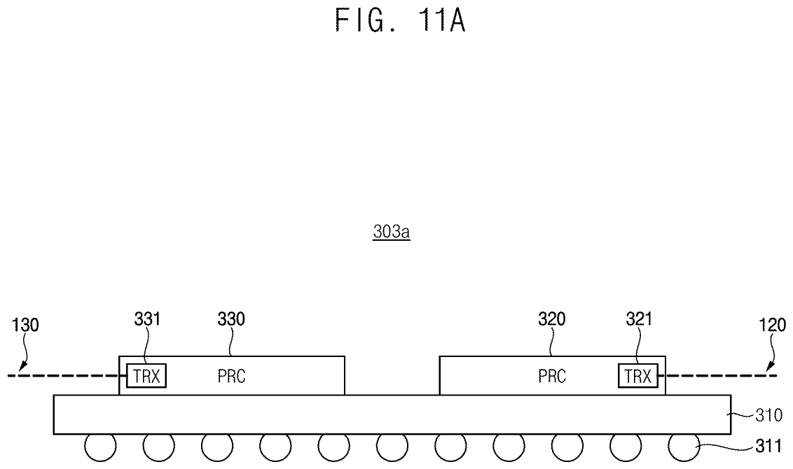

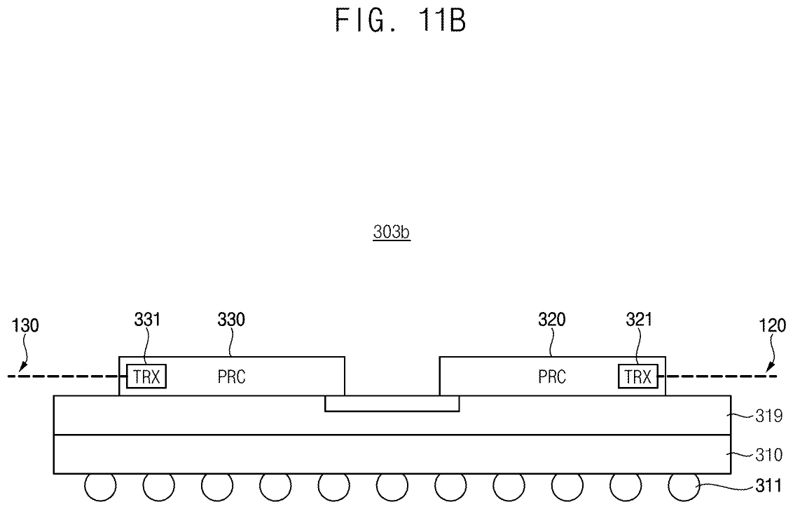

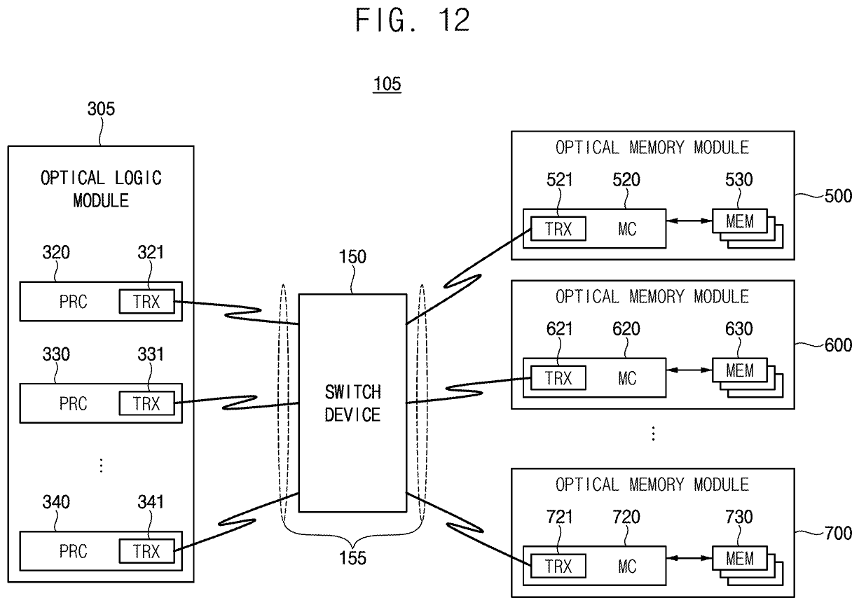

FIGS. 11A and 11B are cross-sectional views of examples of an optical logic module according to example embodiments. The descriptions repeated with FIG. 3 will be omitted.

Referring to FIG. 11A, an optical logic module 303a may include a substrate 310 and processing devices 320 and 330.

The processing devices 320 and 330 may be spaced apart from each other on the substrate 310. In an example of FIG. 11A, the processing devices 320 and 330 may not be electrically connected to each other.

Referring to FIG. 11B, an optical logic module 303b may include a substrate 310 and processing devices 320 and 330.

The processing devices 320 and 330 may be spaced apart from each other on the substrate 310. An internal connection structure 319 may be formed between the substrate 310 and the processing devices 320 and 330. In an example of FIG. 11B, the processing devices 320 and 330 may be electrically connected to each other through connection wires included in the internal connection structure 319. For example, the internal connection structure 319 may be similar to the internal connection structure 519 in FIG. 6B, and may be an interposer or a redistribution layer.

FIG. 12 is a block diagram illustrating an optical memory module and an optical computing system including the optical memory module according to example embodiments. The descriptions repeated with FIGS. 1, 9 and 10 will be omitted.

Referring to FIG. 12, an optical computing system 105 includes a switch device 150, optical interconnections 155, an optical logic module 305 and a plurality of optical memory modules 500, 600 and 700.

The optical computing system 105 may be substantially the same as the optical computing system 100 of FIG. 1, except that the optical computing system 105 further includes the switch device 150 and a configuration of the optical computing system 105 is partially changed.

The optical logic module 305 may include a plurality of processing devices 320, 330 and 340, and the plurality of processing devices 320, 330 and 340 may include a plurality of transceivers 321, 331 and 341, respectively. For example, the number of the processing devices 320, 330 and 340 may be X, where X is a positive integer greater than or equal to two. The optical logic module 305 may be substantially the same as that described with reference to FIG. 10, except that the number of the processing devices 320, 330 and 340 is changed.

The plurality of optical memory modules 500, 600, and 700 may include a plurality of memory controllers 520, 620 and 720 and a plurality of memory devices 530, 630 and 730, respectively. The plurality of memory controllers 520, 620 and 720 may include a plurality of transceivers 521, 621 and 721, respectively. For example, the number of the optical memory modules 500, 600 and 700 may be Y, where Y is a positive integer greater than or equal to two. Each of the optical memory modules 500, 600 and 700 may be substantially the same as that described with reference to FIG. 1.

The switch device 150 may be located or disposed between the optical logic module 305 and the optical memory modules 500, 600 and 700, and may be connected to the optical logic module 305 and the optical memory modules 500, 600 and 700 through the optical interconnections 155. The switch device 150 may control connections between the optical logic module 305 and the optical memory modules 500, 600 and 700. For example, by the switch device 150, the processing devices 320, 330 and 340 and the optical memory modules 500, 600 and 700 may be connected one-to-one correspondence. For example, by the switch device 150, one processing device may be connected to two or more optical memory modules, and/or two or more processing devices may be connected to one optical memory module. For example, depending on an operating state, condition and/or environment of the optical computing system 105, connections between the processing devices 320, 330 and 340 and the optical memory modules 500, 600 and 700 may be dynamically/adaptively changed or adjusted.

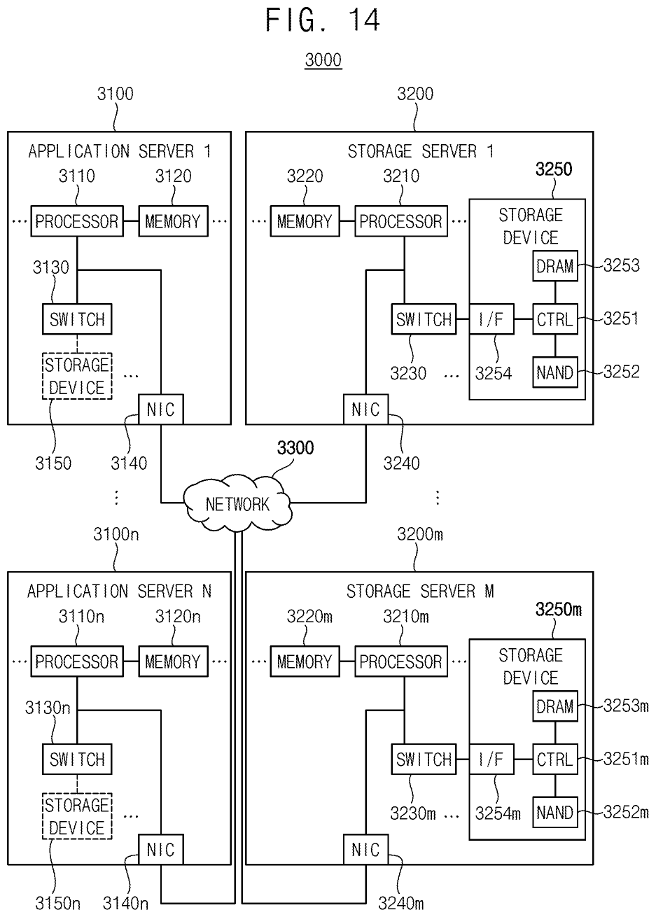

FIG. 13 is a block diagram illustrating an electronic system according to example embodiments.

Referring to FIG. 13, an electronic system 1000 may include a processor 1010, a memory 1020, a connectivity 1030, an input/output (I/O) device 1040, a power supply 1050 and a display device 1060. The electronic system 1000 may further include a plurality of ports for communicating a video card, a sound card, a memory card, a universal serial bus (USB) device, other electronic devices, etc.

The processor 1010 may control operations of the electronic system 1000. The processor 1010 may execute an operating system and at least one application to provide an internet browser, games, videos, or the like. The memory 1020 may store data for the operations of the electronic system 1000. The connectivity 1030 may communicate with an external device and/or system. The I/O device 1040 may include an input device, e.g., a keyboard, a keypad, a mouse, a touchpad, a touch-screen, a remote controller, etc., and an output device, e.g., a printer, a speaker, etc. The power supply 1050 may provide a power for the operations of the electronic system 1000. The display device 1060 may display images provided to a user.

The processor 1010 and the memory 1020 may include a transceiver 1011 and a transceiver 1021, respectively. The processor 1010 and the memory 1020 may be implemented in the form of the optical logic module and the optical memory module according to example embodiments.

FIG. 14 is a block diagram illustrating a data center including a storage device according to example embodiments.

Referring to FIG. 14, a data center 3000 may be a facility that collects various types of data and provides various services, and may be referred to as a data storage center. The data center 3000 may be a system for operating search engines and databases, and may be a computing system used by companies, e.g., banks or government agencies. The data center 3000 may include application servers 3100 to 3100n and storage servers 3200 to 3200m. The number of the application servers 3100 to 3100n and the number of the storage servers 3200 to 3200m may be variously selected according to example embodiments, and the number of the application servers 3100 to 3100n and the number of the storage servers 3200 to 3200m may be different from each other.

The application server 3100 may include at least one processor 3110 and at least one memory 3120, and the storage server 3200 may include at least one processor 3210 and at least one memory 3220. An operation of the storage server 3200 will be described as an example. The processor 3210 may control overall operations of the storage server 3200, and may access the memory 3220 to execute instructions and/or data loaded in the memory 3220. The memory 3220 may include at least one of a double data rate (DDR) synchronous dynamic random access memory (SDRAM), a high bandwidth memory (HBM), a hybrid memory cube (HMC), a dual in-line memory module (DIMM), an Optane DIMM, a nonvolatile DIMM (NVDIMM), etc. The number of the processors 3210 and the number of the memories 3220 included in the storage server 3200 may be variously selected according to example embodiments. In some example embodiments, the processor 3210 and the memory 3220 may provide a processor-memory pair. In some example embodiments, the number of the processors 3210 and the number of the memories 3220 may be different from each other. The processor 3210 may include a single core processor or a multiple core processor. The above description of the storage server 3200 may be similarly applied to the application server 3100. The application server 3100 may include at least one storage device 3150, and the storage server 3200 may include at least one storage device 3250. In some example embodiments, the application server 3100 may not include the storage device 3150. The number of the storage devices 3250 included in the storage server 3200 may be variously selected according to example embodiments.

The application servers 3100 to 3100n and the storage servers 3200 to 3200m may communicate with each other through a network 3300. The network 3300 may be implemented using a fiber channel (FC) or an Ethernet. The FC may be a medium used for a relatively high speed data transmission, and an optical switch that provides high performance and/or high availability may be used. The storage servers 3200 to 3200m may be provided as file storages, block storages or object storages according to an access scheme of the network 3300.

In some example embodiments, the network 3300 may be a storage-only network or a network dedicated to a storage, e.g., a storage area network (SAN). For example, the SAN may be an FC-SAN that uses an FC network and is implemented according to an FC protocol (FCP). For another example, the SAN may be an IP-SAN that uses a transmission control protocol/internet protocol (TCP/IP) network and is implemented according to an iSCSI (a SCSI over TCP/IP or an Internet SCSI) protocol. In other example embodiments, the network 3300 may be a general network, e.g., the TCP/IP network. For example, the network 3300 may be implemented according to at least one protocol, e.g., an FC over Ethernet (FCOE), a network attached storage (NAS), a nonvolatile memory express (NVMe) over Fabrics (NVMe-oF), etc.

Hereinafter, example embodiments will be described based on the application server 3100 and the storage server 3200. The description of the application server 3100 may be applied to the other application server 3100n, and the description of the storage server 3200 may be applied to the other storage server 3200m.

The application server 3100 may store data requested to be stored by a user or a client into one of the storage servers 3200 to 3200m through the network 3300. In addition, the application server 3100 may obtain data requested to be read by the user or the client from one of the storage servers 3200 to 3200m through the network 3300. For example, the application server 3100 may be implemented as a web server or a database management system (DBMS).

The application server 3100 may access a memory 3120n or a storage device 3150n included in the other application server 3100n through the network 3300, and/or may access the memories 3220 to 3220m or the storage devices 3250 to 3250m included in the storage servers 3200 to 3200m through the network 3300. Thus, the application server 3100 may perform various operations on data stored in the application servers 3100 to 3100n and/or the storage servers 3200 to 3200m. For example, the application server 3100 may execute a command for moving or copying data between the application servers 3100 to 3100n and/or the storage servers 3200 to 3200m. The data may be transferred from the storage devices 3250 to 3250m of the storage servers 3200 to 3200m to the memories 3120 to 3120n of the application servers 3100 to 3100n directly or through the memories 3220 to 3220m of the storage servers 3200 to 3200m. For example, the data transferred through the network 3300 may be encrypted data for security or privacy.

In the storage server 3200, an interface 3254 may provide a physical connection between the processor 3210 and a controller 3251 and/or a physical connection between a network interface card (NIC) 3240 and the controller 3251. For example, the interface 3254 may be implemented based on a direct attached storage (DAS) scheme in which the storage device 3250 is directly connected with a dedicated cable. For example, the interface 3254 may be implemented based on at least one of various interface schemes, e.g., an advanced technology attachment (ATA), a serial ATA (SATA) an external SATA (e-SATA), a small computer system interface (SCSI), a serial attached SCSI (SAS), a peripheral component interconnection (PCI), a PCI express (PCIe), an NVMe, a compute express link (CXL), an IEEE 1394, a universal serial bus (USB), a secure digital (SD) card interface, a multi-media card (MMC) interface, an embedded MMC (eMMC) interface, a universal flash storage (UFS) interface, an embedded UFS (eUFS) interface, a compact flash (CF) card interface, etc.

The storage server 3200 may further include a switch 3230 and the NIC 3240. The switch 3230 may selectively connect the processor 3210 with the storage device 3250 or may selectively connect the NIC 3240 with the storage device 3250 under a control of the processor 3210. Similarly, the application server 3100 may further include a switch 3130 and an NIC 3140.

In some example embodiments, the NIC 3240 may include a network interface card, a network adapter, or the like. The NIC 3240 may be connected to the network 3300 through a wired interface, a wireless interface, a Bluetooth interface, an optical interface, or the like. The NIC 3240 may further include an internal memory, a digital signal processor (DSP), a host bus interface, or the like, and may be connected to the processor 3210 and/or the switch 3230 through the host bus interface. The host bus interface may be implemented as one of the above-described examples of the interface 3254. In some example embodiments, the NIC 3240 may be integrated with at least one of the processor 3210, the switch 3230 and the storage device 3250.

In the storage servers 3200 to 3200m and/or the application servers 3100 to 3100n, the processor may transmit a command to the storage devices 3150 to 3150n and 3250 to 3250m or the memories 3120 to 3120n and 3220 to 3220m to program or read data. For example, the data may be error-corrected data by an error correction code (ECC) engine. For example, the data may be processed by a data bus inversion (DBI) or a data masking (DM), and may include a cyclic redundancy code (CRC) information. For example, the data may be encrypted data for security or privacy.

The storage devices 3150 to 3150m and 3250 to 3250m may transmit a control signal and command/address signals to NAND flash memory devices 3252 to 3252m in response to a read command received from the processor. When data is read from the NAND flash memory devices 3252 to 3252m, a read enable (RE) signal may be input as a data output control signal and may serve to output data to a DQ bus. A data strobe signal (DQS) may be generated using the RE signal. The command and address signals may be latched in a page buffer based on a rising edge or a falling edge of a write enable (WE) signal.

The controller 3251 may control overall operations of the storage device 3250. In some example embodiments, the controller 3251 may include a static random access memory (SRAM). The controller 3251 may write data into the NAND flash memory device 3252 in response to a write command, or may read data from the NAND flash memory device 3252 in response to a read command. For example, the write command and/or the read command may be provided from the processor 3210 in the storage server 3200, the processor 3210m in the other storage server 3200m, or the processors 3110 to 3110n in the application servers 3100 to 3100n. A DRAM 3253 may temporarily store (e.g., may buffer) data to be written to the NAND flash memory device 3252 or data read from the NAND flash memory device 3252. Further, the DRAM 3253 may store meta data. The meta data may be data generated by the controller 3251 to manage user data or the NAND flash memory device 3252.

Among the processors 3110 to 3110n and 3210 to 3210n and the memories 3120 to 3120n and 3220 to 3220n included in the application servers 3100 to 3100n and the storage servers 3200 to 3200m, the processor and the memory included in one server may be implemented in the form of the optical logic module and the optical memory module according to example embodiments.

The example embodiments may be applied to various electronic devices and systems that include the memory devices. For example, the example embodiments may be applied to systems, e.g., a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

By way of summation and review, at least one example embodiment of the present disclosure provides an optical memory module capable of efficiently communicating with an external optical logic module using an optical interconnection. At least one example embodiment of the present disclosure provides an optical computing system including the optical memory module and the optical logic module.

That is, in the optical memory module and the optical computing system according to example embodiments, the memory disaggregation may be implemented using co-packaged optics (CPO) technology. For example, the optical logic module including the processing device and the optical memory module including memory devices may be implemented in the disaggregated or separate packages, rather than implementing the processing device and the memory devices in a single package, and the optical logic module and the optical memory module may be optically connected through an optical interconnection. In addition, the transceivers for connection to the optical interconnection may be formed within the processing device and the memory controller, respectively. Accordingly, capacity (or density) and bandwidth of the memory devices connected to one processing device may be efficiently expanded, manufacturing cost may be reduced by connecting the processing device with the memory devices without an interposer, and problems, e.g., heat generation, power consumption and size constraints, may be efficiently resolved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An optical memory module, comprising:
a substrate;
a first memory controller on the substrate, the first memory controller including a first transceiver configured to receive a first optical input signal through a first optical interconnection or output a first optical output signal through the first optical interconnection, the first memory controller being optically connected to an optical logic module located outside the optical memory module through the first transceiver and the first optical interconnection; and
a plurality of first memory devices on the substrate, the plurality of first memory devices being controlled by the first memory controller and accessed by the optical logic module through the first memory controller, the first transceiver, and the first optical interconnection.

2. The optical memory module as claimed in claim 1, wherein the first transceiver includes:
a photonic integrated circuit configured to generate a first electrical input signal based on the first optical input signal or generate the first optical output signal based on a first electrical output signal; and
an electrical integrated circuit configured to generate a first signal based on the first electrical input signal or generate the first electrical output signal based on a second signal, the first signal being provided to the first memory controller and the plurality of first memory devices, the second signal being provided from the first memory controller and the plurality of first memory devices.

3. The optical memory module as claimed in claim 2, wherein the first transceiver further include a serializer and deserializer configured to perform a serial-to-parallel conversion on the first signal or perform a parallel-to-serial conversion on the second signal.

4. The optical memory module as claimed in claim 1, wherein the optical memory module is a disaggregated package that is physically separated from the optical logic module.

5. The optical memory module as claimed in claim 1, wherein the plurality of first memory devices are on the first memory controller.

6. The optical memory module as claimed in claim 5, wherein the first memory controller and the plurality of first memory devices are connected by a through silicon via.

7. The optical memory module as claimed in claim 1, wherein the plurality of first memory devices are spaced apart from the first memory controller on the substrate.

8. The optical memory module as claimed in claim 7, wherein the first memory controller and the plurality of first memory devices are connected by a bonding wire.

9. The optical memory module as claimed in claim 1, further comprising:
a second memory controller on the substrate, the second memory controller including a second transceiver configured to receive a second optical input signal through a second optical interconnection or output a second optical output signal through the second optical interconnection, the second memory controller being optically connected to the optical logic module through the second transceiver and the second optical interconnection; and
a plurality of second memory devices on the substrate, the plurality of second memory devices being controlled by the second memory controller and accessed by the optical logic module through the second memory controller, the second transceiver and the second optical interconnection.

10. The optical memory module as claimed in claim 1, wherein each of the plurality of first memory devices is one of a high bandwidth memory device and a graphic double data rate memory device.

11. An optical computing system, comprising:
an optical logic module;
a first optical memory module configured to optically communicate with the optical logic module; and
a first optical interconnection configured to optically connect the optical logic module with the first optical memory module,
wherein the optical logic module includes:
a first substrate, and
a first processing device on the first substrate, the first processing device including a first transceiver configured to output a first optical signal through the first optical interconnection or receive a second optical signal through the first optical interconnection, the first processing device being optically connected to the first optical memory module through the first transceiver and the first optical interconnection, and
wherein the first optical memory module includes:
a second substrate,
a first memory controller on the second substrate, the first memory controller including a second transceiver configured to receive the first optical signal through the first optical interconnection or output the second optical signal through the first optical interconnection, the first memory controller being optically connected to the optical logic module through the second transceiver and the first optical interconnection, and
a plurality of first memory devices on the second substrate, the plurality of first memory devices being controlled by the first memory controller and accessed by the optical logic module through the first memory controller, the second transceiver and the first optical interconnection.

12. The optical computing system as claimed in claim 11, wherein the first transceiver includes:
a photonic integrated circuit (PIC) configured to generate the first optical signal based on a first electrical signal or generate a second electrical signal based on the second optical signal; and
an electrical integrated circuit (EIC) configured to generate the first electrical signal based on a first signal or generate a second signal based on the second electrical signal, the first signal being provided from the first processing device, the second signal being provided to the first processing device.

13. The optical computing system as claimed in claim 12, wherein the first transceiver further includes a serializer and deserializer (SERDES) configured to perform a parallel-to-serial conversion on the first signal or perform a serial-to-parallel conversion on the second signal.

14. The optical computing system as claimed in claim 11, wherein the optical logic module and the first optical memory module are disaggregated packages that are physically separated from each other.

15. The optical computing system as claimed in claim 11, further comprising:
a second optical memory module configured to optically communicate with the optical logic module; and
a second optical interconnection configured to optically connect the optical logic module with the second optical memory module.

16. The optical computing system as claimed in claim 15, wherein the optical logic module further includes a second processing device on the first substrate, the second processing device including a third transceiver configured to output a third optical signal through the second optical interconnection or receive a fourth optical signal through the second optical interconnection, the second processing device being optically connected to the second optical memory module through the third transceiver and the second optical interconnection.

17. The optical computing system as claimed in claim 16, wherein the second optical memory module includes:
a third substrate;
a second memory controller on the third substrate, the second memory controller including a fourth transceiver configured to receive the third optical signal through the second optical interconnection or output the fourth optical signal through the second optical interconnection, the second memory controller being optically connected to the optical logic module through the fourth transceiver and the second optical interconnection; and
a plurality of second memory devices on the third substrate, the plurality of second memory devices being controlled by the second memory controller and accessed by the optical logic module through the second memory controller, the fourth transceiver and the second optical interconnection.

18. The optical computing system as claimed in claim 15, further comprising a switch device between the optical logic module and the first and second optical memory modules, the switch device configured to control connections of the optical logic module and the first and second optical memory modules.

19. The optical computing system as claimed in claim 11, wherein the first processing device is one of a central processing unit, a graphic processing unit, and a neural processing unit.

20. An optical memory module, comprising:
a substrate;
a first memory controller on the substrate, the first memory controller including a first transceiver configured to receive a first optical input signal through a first optical interconnection or output a first optical output signal through the first optical interconnection, the first memory controller being optically connected to an optical logic module located outside the optical memory module through the first transceiver and the first optical interconnection;
a plurality of first memory devices on the substrate, the plurality of first memory devices being controlled by the first memory controller and accessed by the optical logic module through the first memory controller, the first transceiver and the first optical interconnection;
a second memory controller on the substrate, the second memory controller including a second transceiver configured to receive a second optical input signal through a second optical interconnection or output a second optical output signal through the second optical interconnection, the second memory controller being optically connected to the optical logic module through the second transceiver and the second optical interconnection; and
a plurality of second memory devices on the substrate, the plurality of second memory devices being controlled by the second memory controller and accessed by the optical logic module through the second memory controller, the second transceiver and the second optical interconnection,
wherein the first transceiver includes:
a photonic integrated circuit (PIC) configured to generate a first electrical input signal based on the first optical input signal or generate the first optical output signal based on a first electrical output signal,
an electrical integrated circuit (EIC) configured to generate a first signal based on the first electrical input signal or generate the first electrical output signal based on a second signal, the first signal being provided to the first memory controller and the plurality of first memory devices, the second signal being provided from the first memory controller and the plurality of first memory devices, and
a serializer and deserializer (SERDES) configured to perform a serial-to-parallel conversion on the first signal or perform a parallel-to-serial conversion on the second signal, and
wherein the optical memory module is a disaggregated package that is physically separated from the optical logic module, and is connected to the optical logic module through the first and second optical interconnections without an interposer.
